(19) United States
(12) Patent Application Publication
(10) Pub. No.: US 2012/0126393 A1
(43) Pub. Date: May 24, 2012

(54) RESIN COMPOSITION, MULTILAYER BODY CONTAINING THE SAME, SEMICONDUCTOR DEVICE, AND FILM

(75) Inventor: Kenji IIda, Chiba-shi (JP)

(73) Assignee: Mitsui Chemicals, Inc., Minato-ku (JP)

(21) Appl. No.: 13/381,507

(22) PCT Filed: Jul. 2, 2010
(86) PCT No.: PCT/JP2010/004364

§ 371 Date: Dec. 29, 2011

(30) Foreign Application Priority Data
Jul. 3, 2009 (JP) 2009-158493
Oct. 9, 2009 (JP) 2009-235645

(51) Int. Cl. H01L 23/48; C08K 7/00; C08L 79/08; B32B 27/00

(52) U.S. Cl. 257/734; 428/473.5; 524/404; 524/606; 257/E23.01

(57) ABSTRACT

Disclosed is a resin composition which has high heat dissipation properties and high electrical insulation properties at the same time, while having low-temperature bondability to a conductor circuit or the like. The resin composition contains (A) a thermoplastic polyimide resin having a glass transition temperature of 160 DEG C or less and (B) an inorganic filler. The aspect ratio, that is the value of length/thickness, of the inorganic filler (B) is 9 or more, and the content of the inorganic filler (B) is 40-70 weight % relative to the total weight of the resin composition. The resin composition has a melt viscoelasticity of 10-300 MPa (inclusive) at 170 DEG C.

### TECHNICAL FIELD

The present invention relates to a resin composition, a multilayer body containing the same, a semiconductor device, and a film.

### BACKGROUND ART

In recent years, a semiconductor integrated circuit is used in various electronic apparatus. Among these, in an apparatus that requires a large electric power, a power module is used on which power elements such as diodes, transistors, and ICs with a high power are mounted. In a power module, a sufficient heat-dissipation property for allowing heat generated from power elements to diffuse and a high electric insulation property (electrical reliability) at a high temperature are demanded.

As an electric insulating material suitable for a power module, an electric insulating material containing (A) an organic material such as a polyimide or a polyphenylene oxide and (B) an inorganic filling material is proposed (See, for example, Patent Literature 1 or the like). In Patent Literature 1, the heat-dissipation property of the electric insulating material is improved by increasing the content (B) of the inorganic filling material.

In addition, a power module having a thermoplastic polyimide layer with reduced film thickness as an electric insulating layer is proposed (See, for example, Patent Literature 2 or the like). In Patent Literature 2, the heat-dissipation property is improved by reducing the film thickness of the thermoplastic polyimide layer.

Further, as a resin composition for sealing an electronic component used in an apparatus for an automobile or the like, a resin composition containing (A) a thermoplastic polyimide resin and (B) boron nitride having an aspect ratio of 10 or more, wherein the content of the boron nitride is 20 to 50 weight % (relative to the total resin composition) is proposed (See, for example, Patent Literature 3 or the like). It is disclosed that this resin composition for sealing has an excellent extension property.

### CITATION LIST

### Patent Literature

PTL 1: Japanese Patent Application Laid-Open No. 06-188530
PTL 2: Japanese Patent Application Laid-Open (JP-A) No. 2007-288054
PTL 3: Japanese Patent No. 2851997

### SUMMARY OF INVENTION

### Technical Problem

However, the insulating resin materials of Patent Literatures 1 and 2 have a high glass transition temperature for obtaining an electrical reliability at a high temperature. For this reason, the insulating resin material cannot be bonded to a conductor circuit or a heat-dissipating plate at a low temperature of 170 to 200° C. and, moreover, a sufficient bonding strength could not be obtained.

In addition, since the insulating resin materials of Patent Literatures 1 and 2 do not have a sufficient heat conductivity, the insulating resin layer needs to have a reduced film thickness in order to obtain a high heat-dissipation property. The insulating resin layer with reduced film thickness has raised a fear of decrease in the electrical reliability (electrical insulation property).

Further, Patent Literature 3 dose not disclose the glass transition temperature and the heat conduction property of the resin composition.

The present invention has been made in view of the above circumstances, and an object thereof is to provide an insulating resin composition which has a high heat-dissipation property and a high electric insulation property at the same time while having a good low-temperature bondability to a conductor circuit or the like, as well as a multilayer body, a semiconductor device, and a film containing the same.

### Solution to Problem

The first one of the present invention relates to the following insulating resin composition.

[1] A resin composition containing a thermoplastic polyimide resin (A) having a glass transition temperature of 160° C. or less and an inorganic filler (B), wherein the aspect ratio of the inorganic filler (B), which is represented by the length/thickness of the inorganic filler (B), is 9 or more; the content of the inorganic filler (B) is 40 to 70 weight % relative to the total weight of the resin composition; and the resin composition has a melt viscoelasticity of 10 MPa or more and 300 MPa or less at 170° C.
[2] The resin composition according to [1], wherein the inorganic filler (B) is boron nitride.
[3] The resin composition according to [1] or [2], wherein the thermoplastic polyimide resin (A) is a polyimide obtained by allowing a tetracarboxylic acid dianhydride component and a diamine component to react, and the diamine component contains at least one of the diamines represented by the following general formulas (1), (2), and (3).

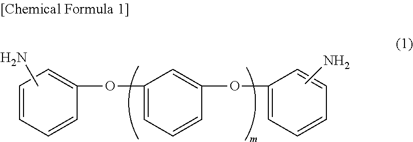

[In the general formula (1), m represents an integer of 1 to 13]

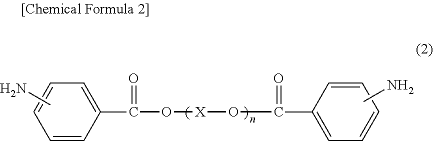

[In the general formula (2), n represents an integer of 1 to 50, and X each independently represents an alkylene group having a carbon number of 1 to 10]

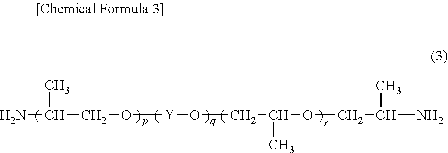

[In the general formula (3), p, q, and r each independently represent an integer of 0 to 10, and Y each independently represents an alkylene group having a carbon number of 1 to 10]

The second one of the present invention relates to the following multilayer body and semiconductor device.

[4] A multilayer body including an insulating resin layer made of a resin composition according to any one of [1] to [3], and a conductor layer disposed on one surface or on both surfaces of the insulating resin layer.
[5] The multilayer body according to [4], wherein the insulating resin layer is formed by laminating and thermally press-bonding two or more dry films made of the resin composition according to any one of [1] to [3], or by repetitively applying and drying the resin composition according to any one of [1] to [3] for two or more times.
[6] A semiconductor device including an insulating resin layer made of a resin composition according to any one of [1] to [3];

a conductor layer disposed on one surface or on both surfaces of the insulating resin layer, the conductor layer having a predetermined circuit pattern; and

a semiconductor element that is joined to the conductor layer.

[7] The semiconductor device according to [6], wherein the semiconductor element is a semiconductor element for electric power having an output capacity of 100 VA or more.
[8] The semiconductor device according to [6] or [7], wherein the insulating resin layer is disposed on a heat-dissipating plate.
[9] The semiconductor device according to any one of [6] to [8], wherein the insulating resin layer is bonded to the conductor layer and the heat-dissipating plate at 10° C. or more and 200° C. or less.
[10] The semiconductor device according to any one of [6] to [9], wherein the insulating resin layer has a thickness of 50 μm or more and 200 μm or less, and the insulating resin layer has an insulation breakdown voltage of 20 kV/mm or more and 300 kV/mm or less.
[11] The semiconductor device according to any one of [6] to [10], wherein the insulating resin layer is formed by laminating and thermally press-bonding two or more dry films made of the resin composition according to any one of [1] to [3], or by repetitively applying and drying the resin composition according to any one of [1] to [3] for two or more times.

The third one of the present invention relates to the following film.

[12] A film made of a resin composition containing a thermoplastic polyimide resin (A) having a glass transition temperature of 160° C. or less and an inorganic filler (B), wherein the aspect ratio of the inorganic filler (B), which is represented by the length/thickness of the inorganic filler (B), is 9 or more;

the content of the inorganic filler (B) is 40 to 70 weight % relative to the total weight of the resin composition;

the resin composition has a melt viscoelasticity of 10 MPa or more and 300 MPa or less at 170° C.; and the film has a heat conductivity of 3.0 W/m·K or more in the thickness direction.

[13] The film according to [12], wherein the film does not contain secondary particles connecting one surface with the other surface of the film.

### Effects of Invention

According to the present invention, an insulating resin composition which has a high heat-dissipation property and a high electric insulation property at the same time while having a good low-temperature bondability to a conductor circuit or the like as well as a multilayer body and a semiconductor device containing the same can be provided.

### BRIEF DESCRIPTION OF DRAWINGS

FIG. 1 is a model view illustrating one example of a construction of a semiconductor device in the present invention.

FIG. 2 is a graph showing a relationship between the application speed in applying a resin composition and an insulation breakdown strength of the obtained resin composition layer.

FIG. 3 is a graph showing a relationship between the temperature-raising time until the resin composition is made to reach a drying temperature and an insulation breakdown strength of the obtained resin composition layer.

FIG. 4 is a TEM photograph showing one example of an agglomeration state of an inorganic filler in the present Example.

### DESCRIPTION OF EMBODIMENTS

The resin composition of the present invention is used, for example, as an insulating resin composition of various electronic components that require a heat conduction property and an electric insulation property, and is preferably used as an insulating resin composition of a semiconductor device having a power device. A power device is a semiconductor element for electric power such as a diode, a transistor, or an IC having a high output capacity, and more specifically is a semiconductor element for electric power having an output capacity of 100 VA or more.

In such a power device having a high output capacity, a large amount of heat is generated. For this reason, a semiconductor device including a power device preferably has a heat-dissipating member for discharging the heat generated in the power device efficiently to the outside of the system. Hereafter, examples of semiconductor devices including a power device will be described.

1. Semiconductor Device

A semiconductor device includes a power device, a conductor layer having a predetermined circuit pattern on which the power device is mounted (joined), and an insulating resin layer that insulates the conductor layer from the other layers, and preferably further includes a heat-dissipating member.

The conductor layer having a predetermined circuit pattern is joined to the power device via an electrically conductive connection layer (for example, a solder layer or the like). The material of the conductor layer may be a metal having an excellent electric conduction property and is, for example, copper, aluminum, or the like.

The insulating resin layer is disposed between the conductor layer having a predetermined circuit pattern and another member (for example, a heat-dissipating member or the like) other than the power device, and has a function of insulating the two. The insulating resin layer contains a resin and an inorganic filler, and has a heat conduction property of a certain degree or more by the inorganic filler. The insulating resin layer preferably has a thickness of 20 to 500 μm, more preferably 50 to 200 μm, in view of ensuring a high electric insulation property.

The heat-dissipating member is not particularly limited and is, for example, a heat-dissipating plate, a heat sink, a cooling pipe, or the like. The heat-dissipating member may be used either alone or as a combination of a plurality of heat-dissipating members.

The heat-dissipating plate is not particularly limited as long as it is a metal plate being excellent in heat conduction property. Examples of the heat-dissipating plates include metal plates made of aluminum, aluminum alloy, copper, iron, stainless steel alloy, invar multilayer metal, or the like. The thickness of the heat-dissipating plate is, for example, about 0.5 to 3.0 mm, though depending on the kind of material thereof.

Other layers may be disposed between the insulating resin layer and the heat-dissipating member. The other layers may be metal layers or resin layers.

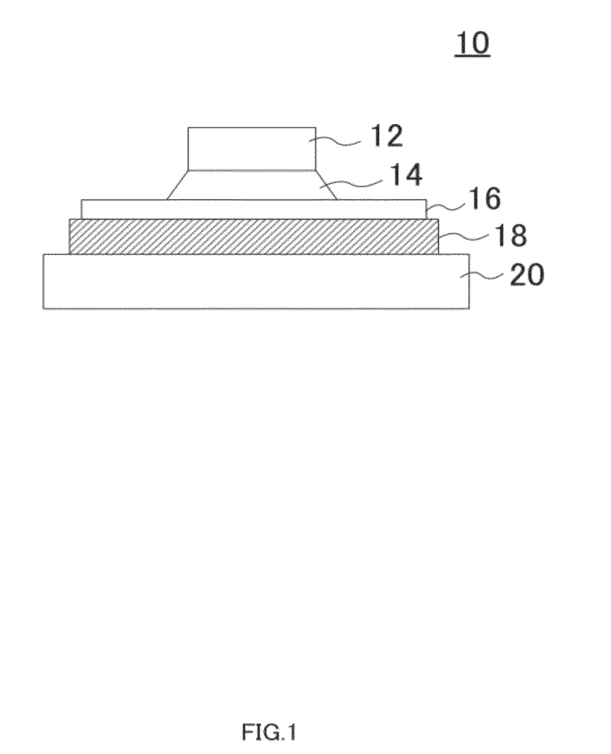

FIG. 1 is a model view showing one example of a construction of semiconductor device 10 of the present invention. Referring to FIG. 1, semiconductor device 10 includes power device 12, conductor layer 16 to which power device 12 is joined via solder layer 14, and heat-dissipating plate 20 disposed under conductor layer 16 via insulating resin layer 18. In this manner, semiconductor device 10 is adapted to dissipate the heat generated in power device 12 by heat-dissipating plate 20 via conductor layer 16 and insulating resin layer 18.

Semiconductor device 10 can be manufactured by various methods. Semiconductor device 10 can be manufactured, for example, through 1) a step of obtaining a multilayer body in which a dry film made of an insulating resin composition and a conductor foil which has not yet been formed into the circuit pattern are successively laminated on heat-dissipating plate 20; 2) a step of thermally press-bonding the multilayer body to obtain insulating resin layer 18 between heat-dissipating plate 20 and conductor layer 16; 3) a step of obtaining conductor layer 16 having a predetermined circuit pattern by performing chemical etching or the like of the conductor foil; and 4) a step of joining conductor layer 16 and power device 12 via solder layer 14.

In the step of 1), a multilayer body obtained by thermally press-bonding the conductor foil and the insulating resin film in advance; or a multilayer body in which insulating resin layer 18 is formed on the conductor foil by applying and drying an adhesive agent (in a form of varnish) of an insulating resin composition may be used instead of separately laminating a dry film made of an insulating resin composition and a conductor foil. The thermal press-bonding of the step of 3) is preferably carried out at a low temperature. The bonding temperature is preferably 10 to 200° C., more preferably 80 to 190° C.

In the case of obtaining insulating resin layer 18 by laminating and thermally press-bonding a dry film of an insulating resin composition, it is preferable to obtain insulating resin layer 18 by laminating and thermally press-bonding two sheets or three or more sheets of thin dry film rather than obtaining insulating resin layer 18 by laminating and thermally press-bonding only one sheet of dry film having a desired thickness. In this case, the dry film may be laminated and thermally press-bonded sheet by sheet, or two or more sheets of dry film may be thermally press-bonded at once after being laminated. Similarly, in the case of obtaining insulating resin layer 18 by applying and drying a varnish of an insulating resin composition, it is preferable to obtain insulating resin layer 18 by applying and drying the varnish repetitively for two times or for three or more times rather than obtaining insulating resin layer 18 by applying and drying the varnish only once. This is for preventing the decrease of insulation property caused by thickness unevenness, application unevenness, microvoids or mingling of foreign substances in advance. In particular, in the case of obtaining insulating resin layer 18 by applying and drying a varnish, the application unevenness of the applied film is eliminated by repetitively carrying out the step of applying and drying a varnish of an insulating resin composition plural times, so that the insulation reliability can be improved. In view of improving the insulation reliability, the step of applying and drying a varnish of an insulating resin composition may be repeated as many times as possible. The laminated insulating resin compositions may have same or different compositions each other.

In such semiconductor device 10, heat conductivity of each layer between power device 12 and heat-dissipating plate 20 must be enhanced in order to enhance the dissipation property of the heat generated in power device 12. In particular, insulating resin layer 18 containing a large amount of resin components has a low heat conductivity as compared with other layers, and is liable to cause decrease in the heat-dissipation property. For this reason, it will be important that insulating resin layer 18 has a high “heat conduction property” in addition to the high “electric insulation property” that insulates conductor layer 16 from other members.

Further, at a high temperature caused by heat generation of power device 12, a stress caused by thermal expansion difference of each layer is liable to be accumulated. For this reason, it will be important that insulating resin layer 18 has in particular a sufficient “bonding strength” to conductor layer 16; and has a suitable “flexibility” of such a degree that the stress can be absorbed.

However, it has been difficult to obtain a high “electric insulation property”, “heat conduction property”, “bonding strength”, and “flexibility” of insulating resin layer 18 at the same time.

Specifically, in order to obtain a sufficient bonding strength of insulating resin layer 18 to conductor layer 16, it is preferable to have a low-temperature bondability (because, when a high-temperature bonding is made, warpage is liable to occur due to thermal expansion difference, thereby causing decrease in the bonding strength). In order to obtain flexibility of insulating resin layer 18, the melt viscoelasticity of the insulating resin composition is preferably set to be less than or equal to a constant value. On the other hand, insulating resin layer 18 having a low-temperature bondability and a low melt viscoelasticity is liable to cause decrease in the electric insulation property at a high temperature. For this reason, in order to obtain both of low-temperature bondability and flexibility without deteriorating the electric insulation property, it is demanded that insulating resin layer 18 is formed to have a large thickness.

However, when insulating resin layer 18 is formed to have a large thickness, the heat-dissipation property will decrease. The heat conductivity of insulating resin layer 18 can be enhanced by increasing the content of the inorganic filler; however, when the content of the inorganic filler is too much, it is not possible to obtain a sufficient bonding strength to the conductor layer.

Therefore, in the present invention, low-temperature bondability and flexibility are realized by appropriate selection of the kind of the resin contained in insulating resin layer 18. Further, by combining a specific resin with an inorganic filler having a specific aspect ratio, an agglomeration structure of the inorganic filler being excellent in heat conductivity (later-mentioned structure having a tertiary assembly) is formed, so as to realize a high heat conductivity of such a degree that a heat-dissipation property larger than or equal to a constant value is obtained even when the thickness is increased. Hereafter, an insulating resin composition constituting insulating resin layer 18 (resin composition of the present invention) will be described.

2. Resin Composition

The resin composition of the present invention contains a resin (A) and an inorganic filler (B), and may contain other arbitrary components in accordance with the needs.

The resin (A) is not particularly limited as long as it is a resin having a glass transition temperature of 160° C. or less. Examples of such resin (A) include epoxy resin, acrylic resin, polyolefin resin, silicone resin, polyamide resin, polyphenylene sulfide resin, polyimide resin, and the like. Among these, resin (A) preferably contains a thermoplastic polyimide resin in view of having a good heat resistance, having flexibility, and the like.

The thermoplastic polyimide resin is a polyimide or a precursor thereof obtained by allowing a mole of a tetracarboxylic acid dianhydride component and b mole of a diamine component to react.

The molar ratio of the tetracarboxylic acid dianhydride component and the diamine component that are allowed to react is preferably within a range of a/b=0.8 to 1.2. This is for obtaining a polymer having a polymerization degree of a constant value or more.

The tetracarboxylic acid dianhydride component that is allowed to react is not particularly limited. The tetracarboxylic acid dianhydride refers to dianhydride of tetracarboxylic acid bonded to an organic group having four or more carbons. In view of heat resistance, it is preferable to use aromatic tetracarboxylic acid dianhydride and, in view of softness, it is preferable to use aliphatic tetracarboxylic acid dianhydride.

Examples of the tetracarboxylic acid dianhydride include oxydiphthalic acid, pyromellitic acid dianhydride, 3-fluoropyromellitic acid dianhydride, 3,6-difluoropyromellitic acid dianhydride, 3,6-bis(trifluoromethyl)pyromellitic acid dianhydride, 1,2,3,4-benzenetetracarboxylic acid dianhydride, 2,2′,3,3′-benzophenonetetracarboxylic acid dianhydride, 3,3′4,4′-biphenyltetracarboxylic acid dianhydride, 3,3″,4,4″-terphenyltetracarboxylic acid dianhydride, 3,3″′,4,4″′-quaterphenyltetracarboxylic acid dianhydride, 3,3″″,4,4″-quincphenyltetracarboxylic acid dianhydride, 2,2′,3,3′-biphenyltetracarboxylic acid dianhydride, methylene-4,4′-diphthalic acid dianhydride, 1,1-ethynylidene-4,4′-diphthalic acid dianhydride, 2,2-propylidene-4,4′-diphthalic acid dianhydride, 1,2-ethylene-4,4′-diphthalic acid dianhydride, 1,3-trimethylene-4,4′-diphthalic acid dianhydride, 1,4-tetramethylene-4,4′-diphthalic acid dianhydride, 1,5-pentamethylene-4,4′-diphthalic acid dianhydride, 2,2-bis(3,4-dicarboxyphenyl)-1,1,1,3,3,3-hexafluoropropane dianhydride, difluoromethylene-4,4′-diphthalic acid dianhydride, 1,1,2,2-tetrafluoro-1,2-ethylene-4,4′-diphthalic acid dianhydride, 1,1,2,2,3,3-hexafluoro-1,3-trimethylene-4,4′-diphthalic acid dianhydride, 1,1,2,2,3,3,4,4-octafluoro-1,4-tetramethylene-4,4′-diphthalic acid dianhydride, 1,1,2,2,3,3,4,4,5,5-decafluoro-1,5-pentamethylene-4,4′-diphthalic acid dianhydride, oxy-4,4′-diphthalic acid dianhydride, thio-4,4′-diphthalic acid dianhydride, sulfonyl-4,4′-diphthalic acid dianhydride, 1,3-bis(3,4-dicarboxyphenyl)-1,1,3,3-tetramethylsiloxane dianhydride, 1,3-bis(3,4-dicarboxyphenyl)benzene dianhydride, 1,4-bis(3,4-dicarboxyphenyl)benzene dianhydride, 1,3-bis(3,4-dicarboxyphenoxy)benzene dianhydride, 1,4-bis(3,4-dicarboxyphenoxy)benzene dianhydride, 1,3-bis[2-(3,4-dicarboxyphenyl)-2-propyl]benzene dianhydride, 1,4-bis[2-(3,4-dicarboxyphenyl)-2-propyl]benzene dianhydride, bis[3-(3,4-dicarboxyphenoxy)phenyl]methane dianhydride, bis[4-(3,4-dicarboxyphenoxy)phenyl]methane dianhydride, 2,2-bis[3-(3,4-dicarboxyphenoxy)phenyl]propane dianhydride, 2,2-bis[4-(3,4-dicarboxyphenoxy)phenyl]propane dianhydride, 2,2-bis[3-(3,4-dicarboxyphenoxy)phenyl]-1,1,1,3,3,3-hexafluoropropane dianhydride, 2,2-bis[4-(3,4-dicarboxyphenoxy)phenyl]propane dianhydride, bis(3,4-dicarboxyphenoxy)dimethylsilane dianhydride, 1,3-bis(3,4-dicarboxyphenoxy)-1,1,3,3-tetramethyldisiloxane dianhydride, 2,3,6,7-naphthalenetetracarboxylic acid dianhydride, 1,2,5,6-naphthalenetetracarboxylic acid dianhydride, 3,4,9,10-perylenetetracarboxylic acid dianhydride, 2,3,6,7-anthracenetetracarboxylic acid dianhydride, 1,2,7,8-phenanthrenetetracarboxylic acid dianhydride, 1,2,3,4-butanetetracarboxylic acid dianhydride, 1,2,3,4-cyclobutanetetracarboxylic acid dianhydride, cyclopentanetetracarboxylic acid dianhydride, cyclohexane-1,2,3,4-tetracarboxylic acid dianhydride, cyclohexane-1,2,4,5-tetracarboxylic acid dianhydride, 3,3′,4,4′-bicyclohexyltetracarboxylic acid dianhydride, carbonyl-4,4′-bis(cyclohexane-1,2-dicarboxylic acid) dianhydride, methylene-4,4′-bis(cyclohexane-1,2-dicarboxylic acid) dianhydride, 1,2-ethylene-4,4′-bis(cyclohexane-1,2-dicarboxylic acid) dianhydride, 1,1-ethynylidene-4,4′-bis(cyclohexane-1,2-dicarboxylic acid)dianhydride, 2,2-propylidene-4,4′-bis(cyclohexane-1,2-dicarboxylic acid)dianhydride, 1,1,1,3,3,3-hexafluoro-2,2-propylidene-4,4′-bis(cyclohexane-1,2-dicarboxylic acid)dianhydride, oxy-4,4′-bis(cyclohexane-1,2-dicarboxylic acid)dianhydride, thio-4,4′-bis(cyclohexane-1,2-dicarboxylic acid)dianhydride, sulfonyl-4,4′-bis(cyclohexane-1,2-dicarboxylic acid)dianhydride, 2,2′-difluoro-3,3′,4,4′-biphenyltetracarboxylic acid dianhydride, 5,5′-difluoro-3,3′,4,4′-biphenyltetracarboxylic acid dianhydride, 6,6′-difluoro-3,3′,4,4′-biphenyltetracarboxylic acid dianhydride, 2,2′,5,5′,6,6′-hexafluoro-3,3′,4,4′-biphenyltetracarboxylic acid dianhydride, 2,2′-bis(trifluoromethyl)-3,3′,4,4′-biphenyltetracarboxylic acid dianhydride, 5,5′-bis(trifluoromethyl)-3,3′,4,4′-biphenyltetracarboxylic acid dianhydride, 6,6′-bis(trifluoromethyl)-3,3′,4,4′-biphenyltetracarboxylic acid dianhydride, 2,2′,5,5′-tetrakis(trifluoromethyl)-3,3′,4,4′-biphenyltetracarboxylic acid dianhydride, 2,2′,6,6′-tetrakis(trifluoromethyl)-3,3′,4,4′-biphenyltetracarboxylic acid dianhydride, 5,5′,6,6′-tetrakis(trifluoromethyl)-3,3′,4,4′-biphenyltetracarboxylic acid dianhydride, 2,2′,5,5′,6,6′-hexakis(trifluoromethyl)-3,3′,4,4′-biphenyltetracarboxylic acid dianhydride, 3,3′-difluorooxy-4,4′-diphthalic acid dianhydride, 5,5′-difluorooxy-4,4′-diphthalic acid dianhydride, 6,6′-difluorooxy-4,4′-diphthalic acid dianhydride, 3,3′,5,5′,6,6′-hexafluorooxy-4,4′-diphthalic acid dianhydride, 3,3′-bis(trifluoromethyl)oxy-4,4′-diphthalic acid dianhydride, 5,5′-bis(trifluoromethyl)oxy-4,4′-diphthalic acid dianhydride, 6,6′-bis(trifluoromethyl)oxy-4,4′-diphthalic acid dianhydride, 3,3′,5,5′-tetrakis(trifluoromethyl)oxy-4,4′-diphthalic acid dianhydride, 3,3′,6,6′-tetrakis(trifluoromethyl)oxy-4,4′-diphthalic acid dianhydride, 5,5′,6,6′-tetrakis(trifluoromethyl)oxy-4,4′-diphthalic acid dianhydride, 3,3′,5,5′,6,6′-hexakis(trifluoromethyl)oxy-4,4′-diphthalic acid dianhydride, 3,3′-difluorosulfonyl-4,4′-diphthalic acid dianhydride, 5,5′-difluorosulfonyl-4,4′-diphthalic acid dianhydride, 6,6′-difluorosulfonyl-4,4′-diphthalic acid dianhydride, 3,3′,5,5′,6,6′-hexafluorosulfonyl-4,4′-diphthalic acid dianhydride, 3,3′-bis(trifluoromethyl)sulfonyl-4,4′-diphthalic acid dianhydride, 5,5′-bis(trifluoromethyl)sulfonyl-4,4′-diphthalic acid dianhydride, 6,6′-bis(trifluoromethyl)sulfonyl-4,4′-diphthalic acid dianhydride, 3,3′,5,5′-tetrakis(trifluoromethyl)sulfonyl-4,4′-diphthalic acid dianhydride, 3,3′,6,6′-tetrakis(trifluoromethyl)sulfonyl-4,4′-diphthalic acid dianhydride, 5,5′,6,6′-tetrakis(trifluoromethyl)sulfonyl-4,4′-diphthalic acid dianhydride, 3,3′,5,5′,6,6′-hexakis(trifluoromethyl)sulfonyl-4,4′-diphthalic acid dianhydride, 3,3′-difluoro-2,2-perfluoropropylidene-4,4′-diphthalic acid dianhydride, 5,5′-difluoro-2,2-perfluoropropylidene-4,4′-diphthalic acid dianhydride, 6,6′-difluoro-2,2-perfluoropropylidene-4,4′-diphthalic acid dianhydride, 3,3′,5,5′,6,6′-hexafluoro-2,2-perfluoropropylidene-4,4′-diphthalic acid dianhydride, 3,3′-bis(trifluoromethyl)-2,2-perfluoropropylidene-4,4′-diphthalic acid dianhydride, 5,5′-bis(trifluoromethyl)-2,2-perfluoropropylidene-4,4′-diphthalic acid dianhydride, 6,6′-difluoro-2,2-perfluoropropylidene-4,4′-diphthalic acid dianhydride, 3,3′,5,5′-tetrakis(trifluoromethyl)-2,2-perfluoropropylidene-4,4′-diphthalic acid dianhydride, 3,3′,6,6′-tetrakis(trifluoromethyl)-2,2-perfluoropropylidene-4,4′-diphthalic acid dianhydride, 5,5′,6,6′-tetrakis(trifluoromethyl)-2,2-perfluoropropylidene-4,4′-diphthalic acid dianhydride, 3,3′,5,5′,6,6′-hexakis(trifluoromethyl)-2,2-perfluoropropylidene-4,4′-diphthalic acid dianhydride, 9-phenyl-9-(trifluoromethyl)xanthene-2,3,6,7-tetracarboxylic acid dianhydride, 9,9-bis(trifluoromethyl)xanthene-2,3,6,7-tetracarboxylic acid dianhydride, bicyclo[2,2,2]octo-7-ene-2,3,5,6-tetracarboxylic acid dianhydride, 9,9-bis[4-(3,4-dicarboxy)phenyl]fluorene dianhydride, 9,9-bis[4-(2,3-dicarboxy)phenyl]fluorene dianhydride, ethylene glycol bistrimellitate dianhydride, and the like.

The diamine component that is allowed to react is not particularly limited; however, it is preferable to contain at least one kind of diamine among the diamine represented by the formula (1), the diamine represented by the formula (2), and the diamine represented by the formula (3) as follows. By setting at least a part of the diamine component to be diamines represented by the formulas (1) to (3), the glass transition temperature of the obtained thermoplastic polyimide resin will decrease, so that the low-temperature bondability and the flexibility of the insulating resin composition containing the thermoplastic polyimide will be enhanced. In addition, the softness of the obtained thermoplastic polyimide resin is high, and the viscosity of the polyimide varnish containing the same is low. For this reason, in the polyimide varnishes having a low viscosity, the inorganic fillers (B) are easy to come closer to each other by van der Waals force so as to form “tertiary assembly of the inorganic fillers (B)” which is mentioned later. In addition, by combining two or more kinds of diamines represented by the formulas (1) to (3), the glass transition temperature can be arbitrarily controlled within a range of ordinary temperature to 200° C. Further, by setting at least a part of the diamine component to be diamines represented by the formulas (1) to (3), a high solubility of the obtained thermoplastic polyimide to solvents can be obtained.

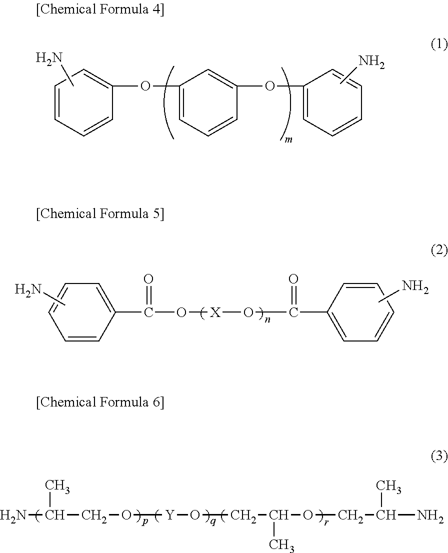

In the formula (1), m represents an integer of 1 to 13.

All or part of the diamine represented by the formula (1) may be a diamine in which the benzene ring contained in the formula (1) has a substituent group. Examples of the diamine in which the benzene ring contained in the formula (1) has a substituent group include 1,3-bis(3-(3-aminophenoxy)phenoxy)-2-methylbenzene, 1,3-bis(3-(4-aminophenoxy)phenoxy)-4-methylbenzene, 1,3-bis(4-(3-aminophenoxy)phenoxy)-2-ethylbenzene, 1,3-bis(3-(2-aminophenoxy)phenoxy)-5-sec-butylbenzene, 1,3-bis(4-(3-aminophenoxy)phenoxy)-2,5-dimethylbenzene, 1,3-bis(4-(2-amino-6-methylphenoxy)phenoxy)benzene, 1,3-bis(2-(2-amino-6-ethylphenoxy)phenoxy)benzene, 1,3-bis(2-(3-aminophenoxy)-4-methylphenoxy)benzene, 1,3-bis(2-(4-aminophenoxy)-4-ter-butylphenoxy)benzene, 1,4-bis(3-(3-aminophenoxy)phenoxy)-2,5-di-tert-butylbenzene, 1,4-bis(3-(4-aminophenoxy)phenoxy)-2,3-dimethylbenzene, 1,4-bis(3-(2-amino-3-propylphenoxy)phenoxy)benzene, 1,2-bis(3-(3-aminophenoxy)phenoxy)-4-methylbenzene, 1,2-bis(3-(4-aminophenoxy)phenoxy)-3-n-butylbenzene, 1,2-bis(3-(2-amino-3-propylphenoxy)phenoxy)benzene, and the like.

In the formula (2), n represents an integer of 1 to 50, preferably an integer of 1 to 20. X each independently represents an alkylene group having a carbon number of 1 to 10, preferably an alkylene group having a carbon number of 1 to 5.

In the formula (3), p, q, and r each independently represent an integer of 0 to 10. Y each independently represents an alkylene group having a carbon number of 1 to 10, preferably an alkylene group having a carbon number of 2 to 10.

In the total diamine component (b mol), the diamine (c mol) represented by the formula (1) is preferably contained within a range of c/b=0.01 to 1, and is more preferably contained within a range of c/b=0.1 to 0.95. In the total diamine component (b mol), the diamine (d mol) represented by the formula (2) is preferably contained within a range of d/b=0.01 to 1, and is more preferably contained within a range of d/b=0.05 to 0.9. In the total diamine component (b mol), the diamine (e mol) represented by the formula (3) is preferably contained within a range of e/b=0.01 to 1, and is more preferably contained within a range of e/b=0.05 to 0.9.

It is more preferable that, in the total diamine component (b mol), all of the diamine represented by the formula (1), the diamine represented by the formula (2), and the diamine represented by the formula (3) are contained.

On the other hand, when (c+d+e)/b is less than 1, the diamine component that is allowed to react contains an arbitrary diamine other than the diamines represented by the formulas (1), (2), and (3). Examples of the arbitrary diamine in the diamine component that is allowed to react include m-phenylenediamine, o-phenylenediamine, p-phenylenediamine, m-aminobenzylamine, p-aminobenzylamine, bis(3-aminophenyl)sulfide, (3-aminophenyl) (4-aminophenyl)sulfide, bis(4-aminophenyl)sulfide, bis(3-aminophenyl) sulfoxide, (3-aminophenyl) (4-aminophenyl) sulfoxide, bis(3-aminophenyl)sulfone, (3-aminophenyl) (4-aminophenyl)sulfone, bis(4-aminophenyl)sulfone, 3,3′-diaminobenzophenone, 3,4′-diaminobenzophenone, 4,4′-diaminobenzophenone, 3,3′-diaminodiphenylmethane, 3,4′-diaminodiphenylmethane, 4,4′-diaminodiphenylmethane, 4,4′-diaminodiphenyl ether, 3,3′-diaminodiphenyl ether, 3,4′-diaminodiphenyl ether, bis[4-(3-aminophenoxy)phenyl]methane, bis[4-(4-aminophenoxy)phenyl]methane, 1,1-bis[4-(3-aminophenoxy)phenyl]ethane, 1,1-bis[4-(4-aminophenoxy)phenyl]ethane, 1,2-bis[4-(3-aminophenoxy)phenyl]ethane, 1,2-bis[4-(4-aminophenoxy)phenyl]ethane, 2,2-bis[4-(3-aminophenoxy)phenyl]propane, 2,2-bis[4-(4-aminophenoxy)phenyl]propane, 2,2-bis[4-(3-aminophenoxy)phenyl]butane, 2,2-bis[3-(3-aminophenoxy)phenyl]-1,1,1,3,3,3-hexafluoropropane, 2,2-bis[4-(4-aminophenoxy)phenyl]-1,1,1,3,3,3-hexafluoropropane, 4,4′-bis(3-aminophenoxy)biphenyl, 4,4′-bis(4-aminophenoxy)biphenyl, bis[4-(3-aminophenoxy)phenyl]ketone, bis[4-(4-aminophenoxy)phenyl]ketone, bis[4-(3-aminophenoxy)phenyl]sulfide, bis[4-(4-aminophenoxy)phenyl]sulfide, bis[4-(3-aminophenoxy)phenyl]sulfoxide, bis[4-(aminophenoxy)phenyl]sulfoxide, bis[4-(3-aminophenoxy)phenyl]sulfone, bis[4-(4-aminophenoxy)phenyl]sulfone, 1,4-bis[4-(3-aminophenoxy)benzoyl]benzene, 1,3-bis[4-(3-aminophenoxy)benzoyl]benzene, 4,4′-bis[3-(4-aminophenoxy)benzoyl]diphenyl ether, 4,4′-bis[3-(3-aminophenoxy)benzoyl]diphenyl ether, 4,4′-bis[4-(4-amino-α,α-dimethylbenzyl)phenoxy]benzophenone, 4,4′-bis[4-(4-amino-α,α-dimethylbenzyl)phenoxy]diphenylsulfone, bis[4-{4-(4-aminophenoxy)phenoxy}phenyl]sulfone, 1,4-bis[4-(4-aminophenoxy)-α,α-dimethylbenzyl)benzene, 1,3-bis[4-(4-aminophenoxy)-α,α-dimethylbenzyl)benzene, bis(3-aminopropyl)tetramethyldisiloxane, 1,3-bis(3-aminopropyl)-1,1,3,3-tetramethyldisiloxane, bis(10-aminodecamethylene)tetramethyldisiloxane, bis(3-aminophenoxymethyl)tetramethyldisiloxane, 1,12-dodecanediamine, norbornanediamine, and the like.

The arbitrary diamine other than the diamines represented by the formulas (1), (2), and (3) is preferably an aromatic diamine in view of the heat resistance, and is preferably an aliphatic diamine or a silicone diamine in view of the softness.

The inorganic filler (B) is not particularly limited as long as it is an inorganic substance having an electric insulation property and a high heat-dissipation property. Examples of the material thereof include boron nitride, aluminum nitride, alumina, alumina hydrate, silicon oxide, silicon nitride, silicon carbide, diamond, hydroxyapatite, barium titanate, and the like. A more preferable material of the inorganic filler (B) is boron nitride or the like.

The content of the inorganic filler (B) in the resin composition can be set to be 40 to 70 weight %, preferably 45 to 60 weight %. The larger the content of the inorganic filler (B) is, the more heat conductivity can be imparted to the resin composition; on the other hand, however, when the content is too much, the bonding property may decrease, and also the flexibility may decrease. When the flexibility decreases, the stress caused by the heat generated in the semiconductor device cannot be absorbed, as described above.

The aspect ratio of the inorganic filler (B) is preferably 9 or more, more preferably 16 or more, still more preferably 20 or more. The aspect ratio refers to the length of the inorganic filler (B)/the thickness of the inorganic filler (B). When the aspect ratio of the inorganic filler (B) is raised, an agglomeration structure of the inorganic fillers (B) with each other can be formed easily, so that a sufficient heat conductivity is obtained even when the content of the inorganic filler (B) is relatively small. The length of the inorganic filler (B) is not particularly limited; however, the length is preferably 100 μm or less.

The resin composition of the present invention may contain an arbitrary component other than the thermoplastic polyimide resin (A) and the inorganic filler (B). Examples of the arbitrary component may contain a surface reforming agent, and examples of the surface reforming agent include a silane coupling agent (C). The surface reforming agent may be used for processing the surface of the filler.

Examples of the silane coupling agent (C) include vinyltrimethoxysilane, vinyltriethoxysilane, vinyltris(2-methoxyethoxy)silane, vinyltrichlorosilane, N-(2-aminoethyl)-3-aminopropylmethyldimethoxysilane, N-(2-aminoethyl)-3-aminopropyltrimethoxysilane, 3-aminopropyltriethoxysilane, N-(2-aminoethyl)-3-aminopropyltriethoxysilane, 3-aminopropyltrimethoxysilane, 3-aminopropyltriethoxysilane, N-phenyl-3-aminopropyltrimethoxysilane, 3-glycidoxypropyltrimethoxysilane, 3-glycidoxypropyltriethoxysilane, 3-glycidoxypropylmethyldimethoxysilane, 3-glycidoxypropylmethyldiethoxysilane, 2-(3,4-epoxycyclohexyl)ethyltrimethoxysilane, 3-isocyanatepropyltriethoxysilane, 3-methacryloxypropyltrimethoxysilane, 3-methacryloxypropylmethyldimethoxysilane, 3-methacryloxypropylmethyldiethoxysilane, 3-methacryloxypropyltriethoxysilane, 3-mercaptopropyltrimethoxysilane, 3-ureidopropyltriethoxysilane, N-(1,3-dimethylbutylidene)-3-(triethoxysilyl)-1-propaneamine, N,N′-bis(3-(trimethoxysilyl)propyl)ethylenediamine, polyoxyethylenepropyltrialkoxysilane, polyethoxydimethylsiloxane, p-styryltrimethoxysilane, 3-acryloxypropyltrimethoxysilane, and the like.

The average particle size of the primary particles of the inorganic filler (B) contained in the resin composition of the present invention is preferably 0.1 to 30 μm. This is for forming secondary particles by agglomerating the particles of the inorganic filler (B) with each other.

It is preferable that the primary particles of the inorganic filler (B) are agglomerated to form secondary particles. The number of the primary particles contained in one secondary particle is preferably 15 to 1000, more preferably 15 to 100. In addition, the average particle size of the secondary particles is preferably 2 to 30 μm.

Further, it is preferable that the secondary particles of the inorganic filler (B) are dispersed in the resin composition but are not uniformly dispersed so that the resin composition may have a region having a high density of the secondary particles (referred to as a “tertiary assembly”). The tertiary assembly means a region in which the secondary particles are arranged at an interval of 0.05 μm or less with each other in the resin composition.

It is preferable that the volume ratio of the tertiary assemblies relative to the resin composition is 20 vol % or more, more preferably vol % or more. The larger the volume ratio of the tertiary assemblies is, the higher the heat conductivity of the resin composition will be.

The volume ratio of the tertiary assemblies relative to the total resin composition can be measured by performing image analysis on an SIM image obtained by performing SIM (Scanning Ion Microscopy) observation on a cross-section of a film made of the resin composition by the following procedure. Specifically, the analysis may be made by the following procedure.

1) The SIM image is binarized in tone. The white region is assumed to be a filler part, and the black region is assumed to be a resin part.

2) From within the white region, the parts in which 15 or more primary particles are agglomerated are extracted as secondary particles.

3) Tertiary assemblies in which the secondary particles are close within 0.05 μm are enclosed with a frame.

4) The ratio of the parts of the tertiary assemblies is calculated from the image.

In addition, it is preferable that the film made of the resin composition of the present invention contains no secondary particle connecting one surface with the other surface of the film. And it is preferable that the film contains no secondary particle connecting one surface with the other surface of the film, one conductive member in contact with the one surface and the other conductive member in contact with the other surface should be insulated each other via the film. If the film made of the resin composition of the present invention contains a secondary particle connecting one surface with the other surface of the film, an insulation breakdown is liable to be generated to decrease the electrical insulation property while having high heat conductivity.

The agglomeration state or the dispersion state of the inorganic filler (B) in the resin composition of the present invention can be confirmed by performing TEM observation on a cross-section of the film made of the resin composition of the present invention.

The agglomeration state or the dispersion state of the inorganic fillers (B) can be controlled mainly by the kind of the thermoplastic polyimide resin (A) in which the inorganic filler (B) is dispersed, the kind of the inorganic filler (B), the treatment (for example, a coupling treatment) state thereof, and the like.

Above all, by setting the diamine constituting the thermoplastic polyimide resin (A) to be a diamine represented by the above-described formulas (1) to (3), the softness of the thermoplastic polyimide resin (A) can be enhanced, and the imide varnish containing the same can be made to have a low viscosity. Then, in the polyimide varnishes having a low viscosity, the inorganic fillers (B) come close to each other easily by van der Waals force, so that a tertiary assembly of the inorganic fillers (B) can be formed in the thermoplastic polyimide resin (A).

A silane coupling agent (C) may be allowed to undergo coupling reaction with the surface of the inorganic filler (B) contained in the resin composition to modify the filler surface. By this, the agglomeration state or the dispersion state of the inorganic filler (B) can be controlled. In addition, the agglomeration state or the dispersion state of the inorganic filler (B) can also be controlled by the resin solid component concentration of the polyimide varnish in which the inorganic filler (B) is dispersed, the agitation condition in dispersing the inorganic filler (B) into the polyimide varnish, and the like.

The resin composition of the present invention has an electrical insulation property above or equal to a constant value. The insulation breakdown voltage of the resin composition is preferably 20 kV/mm or more and 300 kV/mm or less, more preferably 30 kV/mm or more and 250 kV/mm or less.

The insulation breakdown voltage of the resin composition is measured as follows.

1) A pseudo device multilayer structure body obtained by thermally press-bonding a copper foil (electrode) onto both surfaces of a film sample of the resin composition is prepared. The thickness of the film is about 60 μm, and the thickness of the copper foil (electrolytic copper foil) that will be an electrode is about 105 μm.

2) The pseudo device multilayer structure body is subjected to measure by a method that accords to JIS C2110. The measurement apparatus can be HAT-300-100RHO manufactured by Yamayo Tester Co., Ltd. or the like.

The resin composition of the present invention has a high heat conductivity above or equal to a constant value while having the insulation property. The heat conductivity of the resin composition of the present invention is 3.0 W/m·K or more. A resin composition having such a high heat conductivity hardly loses its heat-dissipation property even when made to have a large thickness, so that a high electrical insulation property can be obtained.

The heat conductivity of the resin composition is measured as follows.

1) A film sample of the resin composition is prepared. The film thickness is about 60 μm.

2) The heat diffusion rate cc is measured by the laser flash method. The measurement of the heat diffusion rate by the laser flash method is carried out by irradiating one surface of the film-shaped sample with a pulse laser and measuring the heat quantity from the opposite surface (opposite to the irradiated surface) and the time. The measurement apparatus can be a laser flash method heat constant measuring apparatus (TC-9000) of Ulvac Riko Inc. or the like.

3) The specific heat Cp is measured by the DSC method. The measurement apparatus can be a Diamond DSC apparatus of PerkinElmer Co., Ltd. or the like.

4) The density ρ is determined by dividing the weight measured with an electronic scale by the volume (product of area and thickness) of the film-shaped body.

5) The heat conductivity λ (W/m·K) is calculated by applying the measurement values of the heat diffusion rate α (m²/s), the specific heat Cp (J/(kg·K)), and the density ρ (kg/m³) obtained in 1) to 4) to the following formula (1).

heat conductivity λ=heat diffusion rate α×specific heat Cp×density ρ (1)

The resin composition of the present invention is excellent also in the low-temperature bondability (100 to 200° C.) and the flexibility. The glass transition temperature of the resin (A) contained in the resin composition of the present invention is preferably 160° C. or less. In addition, the melt viscoelasticity at 170° C. of the resin composition of the present invention is 10 MPa or more and 300 MPa or less, preferably 20 MPa or more and 200 MPa or less. When the melt viscoelasticity at 170° C. is 300 MPa or less, a good low-temperature bondability of the resin composition is obtained, and when the melt viscoelasticity is 10 MPa or more, a good heat resistance and shape stability at a high temperature (170° C. or more) of the resin composition are obtained.

The glass transition temperature of the resin (A) and the melt viscoelasticity of the resin composition are measured as follows.

1) With respect to a film sample of the resin composition, the storage elastic modulus E′ and the loss elastic modulus E″ are measured by temperature dispersion measurement (tensile mode) of solid viscoelasticity. The measurement apparatus can be RSA-II manufactured by TA.

2) The peak value of the loss tangent tan δ=E″/E′ obtained from the storage elastic modulus E′ and the loss elastic modulus E″ measured in the 1) is assumed to indicate a glass transition temperature.

3) The value of the storage elastic modulus E′ at 170° C. is assumed to be the melt viscoelasticity at 170° C.

In this manner, the resin composition of the present invention has a sufficient heat conductivity in spite of the fact that the amount of the inorganic filler (B) contained therein is comparatively small. Therefore, even with a resin composition made to have a large thickness, a high heat-dissipation property above or equal to a constant value can be obtained, and is compatible with a high electrical insulation property. In addition, the resin composition of the present invention is excellent in low-temperature bondability and flexibility. For this reason, a sufficient bonding strength to a conductor circuit is obtained even at a high temperature, and a stress or the like generated by thermal expansion difference of each layer can be absorbed.

3. Method of Producing a Resin Composition

In an example in which the resin (A) is a thermoplastic polyimide resin, the resin composition of the present invention may be produced through 1) a step of preparing a polyimide varnish, and 2) a step of blending an inorganic filler (B) with the polyimide varnish and stirring the varnish, and further optional 3) a step of solidifying the polyimide varnish.

The polyimide varnish contains a polyimide resin and preferably a solvent. The resin solid component concentration in the polyimide varnish is preferably 5 to 50 weight %, more preferably 10 to 30 weight %. This is for suitably controlling a later-mentioned condition for stirring.

The kind of the solvent is not particularly limited, and may be, for example, N,N-dimethylformamide, N,N-dimethylacetamide, N,N-diethylformamide, N,N-diethylacetamide, N,N-dimethylmethoxyacetamide, dimethylsulfoxide, hexamethylphosphoramide, N-methyl-2-pyrrolidone, dimethylsulfone, 1,3,5-trimethylbenzene, a mixed solvent of two or more kinds of these, or a mixed solvent of these solvents with benzene, toluene, xylene, benzonitrile, dioxane, cyclohexane, or the like.

The polyimide varnish is obtained by blending an acid dianhydride component and a diamine component in a solvent, synthesizing an amide acid by dehydration reaction, and further forming the resultant into an imide. The acid dianhydride component and the diamine component to be blended may be the above-mentioned components.

An inorganic filler (B) is added to the obtained polyimide varnish. The inorganic filler (B) to be added may be the aforementioned inorganic filler. In addition, the inorganic filler (B) to be added may be modified with a silane coupling agent (C).

By stirring the polyimide varnish to which the inorganic filler (B) has been added, the inorganic filler (B) is dispersed into the polyimide varnish. The stirring may be carried out with use of an ordinary stirrer or disperser such as a stone mill, a three-roll mill, or a ball mill. In addition, the temperature of the polyimide varnish to be stirred is not particularly limited, and may be 10 to 50° C.

The resin composition of the present invention may be in a varnish form or in a film form. In other words, the polyimide varnish itself in which the inorganic filler (B) has been dispersed may be used as an insulating adhesive agent. For example, the polyimide varnish may be applied to a body to be bonded such as a heat-dissipating plate in the above-described semiconductor device. On the other hand, the polyimide varnish may be formed into a film, and the film may be used as an insulating adhesive film. For example, an insulating adhesive film can be obtained by applying the polyimide varnish onto a film subjected to a releasing treatment, solidifying the varnish, and peeling it off. The thickness of the film is typically 10 to 200 μm.

As described above, the layer (film) made of the resin composition of the present invention can be formed by the method of laminating and thermally press-bonding the resin composition being films, the method of applying and drying the resin composition as varnish, or the like. The insulating resin layer is preferably formed by laminating and thermally press-bonding two or three or more films of the resin composition, or by repetitively applying and drying the resin composition as varnish for two or three or more times. This is because the decrease of insulation property caused by thickness unevenness, application unevenness, microvoids or mingling of foreign substances can be prevented in advance. The laminated resin compositions may have same or different compositions each other.

In order to obtain a high electrical insulation property in the case of forming a layer (film) made of the resin composition of the present invention by applying and drying a resin composition as varnish, it is preferable to suppress the voids between the base material (on which the application is made) and the resin composition by adjusting a condition of applying and drying the resin composition as varnish.

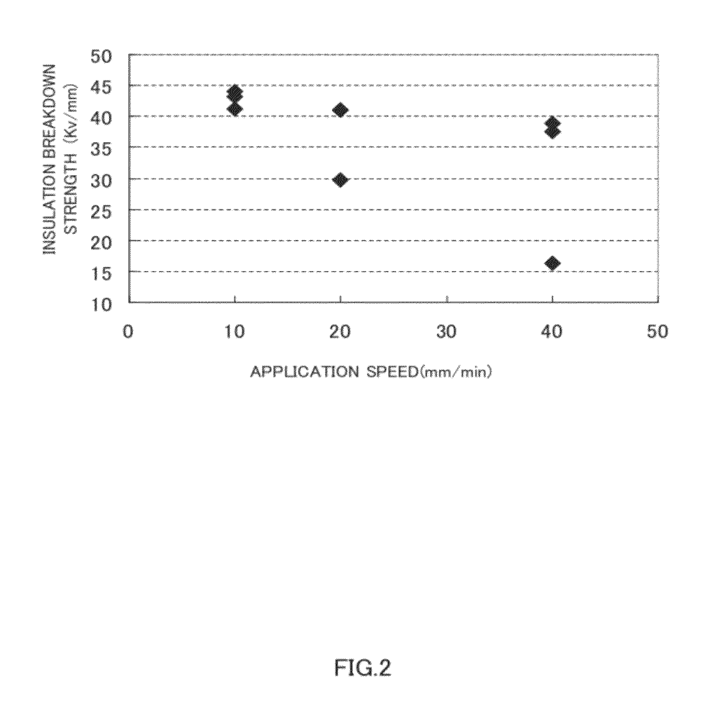

FIG. 2 is a graph showing one example of a relationship between the application speed of applying the resin composition of the present invention and the insulation breakdown strength of the obtained resin composition layer. As shown in FIG. 2, it will be understood that, the smaller the application speed of applying the resin composition is, the higher the electrical insulation property of the obtained resin composition layer is. This seems to be because, when the application speed of applying the resin composition is decreased, the resin composition is sufficiently wetted to the base material, whereby generation of the voids between the base material and the resin composition can be reduced. For this reason, the application speed of applying the resin composition is preferably set to be 1 to 15 mm/minute.

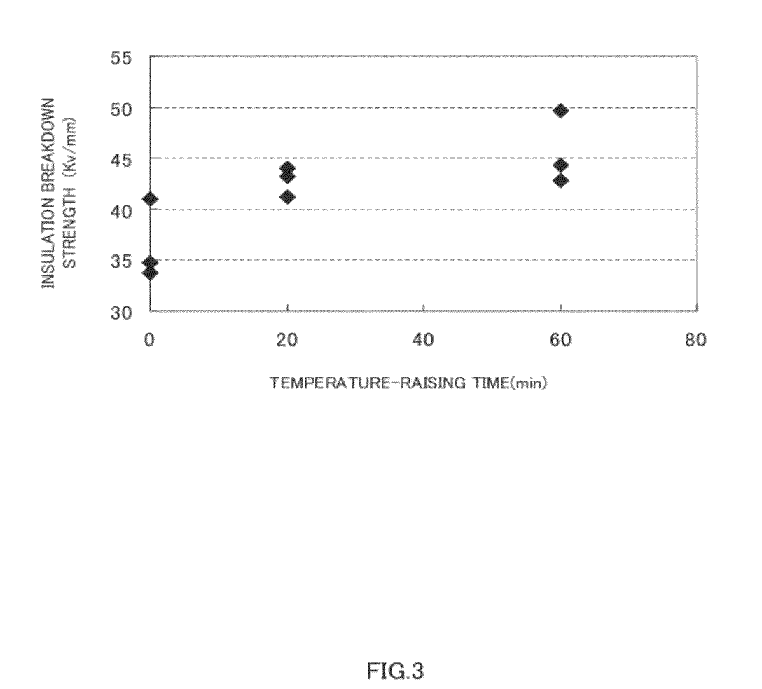

FIG. 3 is a graph showing one example of a relationship between the temperature-raising time until the temperature is raised to 150° C. in drying the applied film of the resin composition of the present invention at 150° C. and an insulation breakdown strength of the obtained resin composition layer. As shown in FIG. 3, it will be understood that, the smaller the speed of raising the temperature of the applied film is, the higher the electric insulation property of the obtained resin composition layer is. This seems to be because, when the speed of raising the temperature of the applied film of the resin composition is decreased, the voids are hardly generated between the base material and the resin composition when the solvent is volatilized. For this reason, the speed of raising the temperature of the applied film of the resin composition is preferably set to be 0.5 to 10.0° C./minute.

Here, in FIGS. 2 and 3, the insulation breakdown strength of the obtained resin composition layer is a value (unit: kV/mm) obtained by measuring the insulation breakdown voltage of the resin composition layer prepared in the same manner as in the Examples and dividing the obtained insulation breakdown voltage by the film thickness.

The resin composition of the present invention is suitably used for bonding to a conductor layer, preferably a metal foil. For example, the resin composition of the present invention can be used as an insulating resin layer that bonds a base material resin film to a metal foil in a circuit board, a heat-dissipating substrate or a component-incorporating substrate, which are multilayer body including the base material resin film and the metal foil (which is preferably a copper foil). In addition, the base material of the substrate for a circuit may be constructed with a film (insulating resin layer) made of the resin composition of the present invention. These substrate for a circuit, heat-dissipating substrate or component-incorporating substrate can be preferably used not only in a semiconductor device on which the above-described power device is mounted but also in a semiconductor device other than that. The insulating resin layer can be obtained by a method similar to the above-described method of obtaining a layer (film) made of the resin composition of the present invention.

The thickness of the multilayer body may be suitably set in accordance with the usage, and is not particularly limited. The thickness of the insulating resin layer made of the resin composition of the present invention is preferably 50 to 200 μm. The multilayer body may be either a flexible body or a rigid body, and is suitably set by selecting the thickness and the material in accordance with the purpose.

Because of having a high fluidity of the resin, the resin composition of the present invention is suitably used not only in a semiconductor device such as described above on which a power device is mounted but also for use in a semiconductor sealing package having an electronic component embedded within the resin, for use in a component-incorporating substrate, or the like.

### Examples

Hereafter, the present invention will be further described with reference to the Examples and the Comparative Examples. The technical scope of the present invention is not limited by these.

Compounds used in the Examples or the Comparative Examples will be shown below.

1) diamine

APB: 1,3-bis(3-aminophenoxy)benzene (manufactured by Mitsui Chemical Inc.)

14EL: polytetramethyleneoxide di-p-aminobenzoate

(ERASMER1000) (manufactured by Ihara Chemical Co., Ltd.)

XTJ-542: polyetheramine represented by the following formula (trade name: JEFFERMINE, manufactured by Huntsman International LLC.)

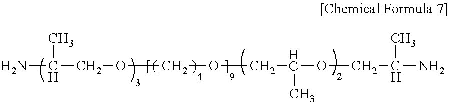

2) acid dianhydride

s-BPDA: 3,3′,4,4′-biphenyltetracarboxylic acid dianhydride (manufactured by JFE Chemical Corporation)

p-BAPP: 2,2-bis[4-(4-aminophenoxy)phenyl]propane

### Example 1

### Preparation of Polyimide Varnish

Into a solvent adjusted to contain NMP and mesitylene at a ratio of 7/3, two kinds of diamines (APB, 14EL) and one kind of acid dianhydride (s-BPDA) shown in the above were blended in a molar ratio of APB:14EL:s-BPDA=0.8:0.2:1.0. The obtained mixture was stirred for 4 hours or more in a flask into which dried nitrogen gas can be introduced, so as to obtain a polyamic acid solution having a resin solid component weight of 20 to 25 weight %. After sufficient stirring, the reaction system was heated to about 180° C. while being stirred in a flask equipped with a Dienstag tube, and the water produced by the dehydration reaction was taken out of the system to obtain a polyimide varnish.

Blending of Filler

A boron nitride filler (trade name: UHP-2, manufactured by Showa Denko K.K., with an aspect ratio of 16) was blended into the polyimide varnish so that the blending amount of the filler would be 50 weight % relative to the total weight of the resin solid component and the filler, followed by stirring for dispersion. The stirring was carried out in such a manner that, after initial stirring was carried out using “AWATORI RENTARO (type number (ARE310), Thinky Corporation)”, stirring and kneading were carried out using a three-roll mill. As a result thereof, a polyimide varnish solution blended with a filler was obtained.

Preparation of Film

The polyimide varnish solution blended with a filler was applied at a speed of 10 mm/sec onto a PET film subjected to a releasing treatment. The obtained applied film was dried at 130° C. for 30 minutes to remove the solvent. After drying, the film part was peeled off from the PET film by using forceps or the like, so as to prepare a polyimide film (having a film thickness of 60 μm) into which the boron nitride filler are dispersed.

### Example 2

A polyimide film was prepared in the same manner as in Example 1 except that two kinds of diamines (APB, XTJ-542) and one kind of acid dianhydride (s-BPDA) were blended in a molar ratio of APB:XTJ-542:s-BPDA=0.8:0.2:1.0.

### Example 3

A polyimide film was prepared in the same manner as in Example 1 except that three kinds of diamines (APB, 14EL, XTJ-542) and one kind of acid dianhydride (s-BPDA) were blended in a molar ratio of APB:14EL:XTJ-542:s-BPDA=0.8:0.15:0.05:1.0, and that the blending amount of the boron nitride filler was set to be 55 weight %.

### Example 4

A polyimide film similar to that of Example 1 was prepared except that the film thickness of the polyimide film was set to be 15 μm.

### Example 5

A polyimide film similar to that of Example 1 was prepared except that UHP-1 (manufactured by Showa Denko K.K., aspect ratio: 20) was used as the boron nitride filler.

### Example 6

A polyimide film layer, which is the first layer, having a thickness of about 30 μm was obtained by applying and drying a polyimide varnish similar to that of Example 1 on a PET film subjected to a releasing treatment in a step of preparing a film. A polyimide film layer, which is the second layer, having a thickness of about 30 μm was formed on the polyimide film by applying and drying a polyimide varnish similar to that of Example 1, so as to obtain a polyimide film having a total thickness of about 60 μm.

### Comparative Example 1

A polyimide film similar to that of Example 1 was prepared except that one kind of diamine (p-BAPP) and one kind of acid dianhydride (s-BPDA) were blended in a molar ratio of p-BAPP:s-BPDA=1.0:1.0.

### Comparative Example 2

A polyimide film similar to that of Example 1 was prepared except that the blending amount of the boron nitride filler was set to be 35 weight %.

### Comparative Example 3

A polyimide film similar to that of Example 1 was prepared except that the blending amount of the boron nitride filler was set to be 75 weight %.

### Comparative Example 4

A polyimide film similar to that of Example 1 was prepared except that UHP-S1 (manufactured by Showa Denko K.K., aspect ratio: around 6) was used as the boron nitride filler.

### Comparative Example 5

A polyimide film similar to that of Example 1 was prepared except that UHP-S1 (manufactured by Showa Denko K.K., aspect ratio: around 6) was used as the boron nitride filler, and that the blending amount of the filler was set to be 85 weight %.

### Comparative Example 6

A polyimide film similar to that of Example 1 was prepared except that GP (manufactured by Denki Kagaku Kogyo Kabushiki Kaisha, aspect ratio: around 8.7) was used as the boron nitride filler.

### Comparative Example 7

A polyimide film similar to that of Example 1 was prepared except that spherical alumina DAW07 (manufactured by Denki Kagaku Kogyo Kabushiki Kaisha, aspect ratio: about 1) was used instead of the boron nitride filler.

### Comparative Example 8

A polyimide film similar to that of Example 1 was prepared except that spherical alumina DAW07 (manufactured by Denki Kagaku Kogyo Kabushiki Kaisha, aspect ratio: about 1) was used instead of the boron nitride filler, and that the blending amount of the spherical alumina was set to be 85 weight %.

The conditions for preparing a film in Examples 1 to 6 and Comparative Examples 1 to 8 are summarized in Table 1.

TABLE 1

| | thermoplastic polyimide (A) | | inorganic filler (B) | | | film |
|---|---|---|---|---|---|---|
| | | acid | | | content | thickness |
| | diamine (molar ratio) | dianhydride | kind | aspect ratio | (weight %) | (μm) |
| Example 1 | APB/14EL (0.8/0.2) | s-BPDA | boron nitride | 16 | 50 | 60 |
| Example 2 | APB/XTJ-542 (0.8/0.2) | s-BPDA | boron nitride | 16 | 50 | 60 |
| Example 3 | APB/14EL/XTJ-542 | s-BPDA | boron nitride | 16 | 55 | 60 |
| | (0.8/0.15/0.05) | | | | | |
| Example 4 | APB/14EL (0.8/0.2) | s-BPDA | boron nitride | 16 | 50 | 15 |
| Example 5 | APB/14EL (0.8/0.2) | s-BPDA | boron nitride | 20 | 50 | 60 |
| Example 6 | APB/14EL (0.8/0.2) | s-BPDA | boron nitride | 16 | 50 | 60 (applied twice) |
| Comparative | p-BAPP | s-BPDA | boron nitride | 16 | 50 | 60 |
| Example 1 | | | | | | |
| Comparative | APB/14EL (0.8/0.2) | s-BPDA | boron nitride | 16 | 35 | 60 |
| Example 2 | | | | | | |
| Comparative | APB/14EL (0.8/0.2) | s-BPDA | boron nitride | 16 | 75 | 60 |
| Example 3 | | | | | | |
| Comparative | APB/14EL (0.8/0.2) | s-BPDA | boron nitride | ~6 | 50 | 60 |
| Example 4 | | | | | | |
| Comparative | APB/14EL (0.8/0.2) | s-BPDA | boron nitride | ~6 | 85 | 60 |
| Example 5 | | | | | | |
| Comparative | APB/14EL (0.8/0.2) | s-BPDA | boron nitride | ~8.7 | 50 | 60 |
| Example 6 | | | | | | |
| Comparative | APB/14EL (0.8/0.2) | s-BPDA | spherical alumina | about 1 | 50 | 60 |
| Example 7 | | | | | | |
| Comparative | APB/14EL (0.8/0.2) | s-BPDA | spherical alumina | about 1 | 85 | 60 |
| Example 8 | | | | | | |

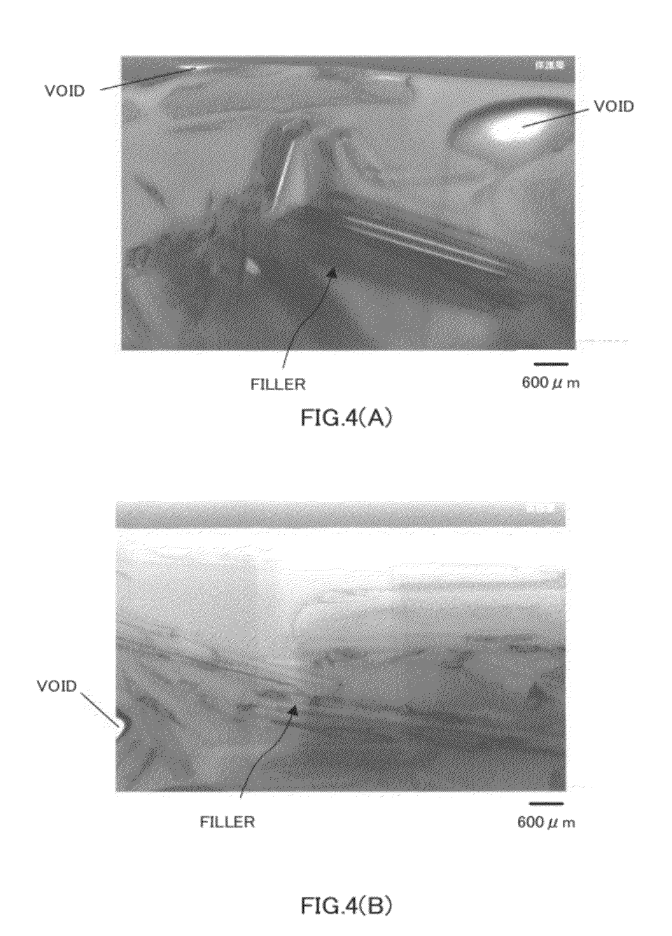

The heat conductivity, the glass transition temperature, the melt viscoelasticity, the bonding strength, and the electric insulation property of the polyimide film obtained in each of the Examples and Comparative Examples were evaluated in the following manner. These results are shown in Table 2. Further, with respect to the polyimide films obtained in part of the Examples, an agglomeration state of the inorganic filler was observed. A TEM photograph of Example 1 is shown in FIG. 4(A), and aTEM photograph of Example 5 is shown in FIG. 4(B).

Measurement of Heat Conductivity

The heat conductivity of the prepared polyimide films was evaluated. Specifically, the heat conductivity was calculated by measuring “heat diffusion rate α”, “specific heat Cp” and “density ρ” of a sample and applying those measurement values to the following formula.

Heat conductivity λ=heat diffusion rate α×specific heat Cp×density ρ

The heat diffusion rate was measured by the laser flash method. As the measurement apparatus, a laser flash method heat constant measuring apparatus (TC-9000) manufactured by Ulvac Riko Inc. was used. The specific heat was measured by the DSC method. As the measurement device, a Diamond DSC apparatus manufactured by PerkinElmer Co., Ltd. was used. The weight was measured by an electronic scale, and the volume was calculated from the sample area and the sample thickness, so as to calculate the density.

Measurement of Glass Transition Temperature and Melt Viscoelasticity

The storage elastic modulus E′ and the loss elastic modulus E″ of the prepared polyimide films were evaluated by the temperature dispersion measurement (tensile mode) of the solid viscoelasticity, and the glass transition temperature was deduced from the peak value of the loss tangent tan δ=E″/E′. The melt viscoelasticity was assumed to be the value of the storage elastic modulus E′ at 170° C. As the measurement device, RSA-II manufactured by TA Instruments. was used.

Measurement of Bonding Strength

The bonding strength of the prepared polyimide film was evaluated. Specifically, the prepared polyimide film was cut out to a predetermined size. A rolled copper foil having a thickness of 18 μm (trade name: BHY-22B-T, manufactured by Nippon Mining & Metals Co., Ltd.) was superposed on both surfaces of the cut-out film. Further, the resultant was pressed under temperature, time, and pressure conditions of 180° C.×60 minutes×25 kg/cm², so as to form a multilayer. Several pieces of mask parts were prepared by bonding an IC tape having a dimension of 3.2 mm width×30 mm length onto the copper foil surface of the pressed multilayer sample. The copper around the mask parts were removed by etching using an aqueous solution of ferric chloride, so as to form a copper pattern for bonding strength measurement. The end of the formed copper pattern was flicked up, and the copper pattern was pulled vertically to the film surface, so as to measure the bonding strength between the copper and the film sample.

Measurement of Electric Insulation Property

The insulation breakdown voltage of the prepared polyimide film and the insulation breakdown voltage of the pseudo device multilayer structure body in which a copper layer was formed on both surfaces of the polyimide film were respectively evaluated. The pseudo device multilayer structure body was prepared in the following manner. First, after the polyimide film was cut out to a predetermined size, an electrolytic copper foil having a thickness of 105 μm (trade name: SLP-105WB, manufactured by Nippon Denkai, Ltd.) was superposed on both surfaces of the film, and the resultant was pressed under temperature, time, and pressure conditions of 180° C.×60 minutes×25 kg/cm², so as to form a multilayer. The outer peripheral parts of the copper foil on one surface of the pressed multilayer sample (1 mm or more from the outer circumferential end) were removed by etching using an aqueous solution of ferric chloride, so as to prepare a pseudo device multilayer structure body. For measurement of the insulation breakdown voltage of the pseudo device multilayer structure body, the copper foil parts formed on both surfaces were used as electrodes. Then, the insulation breakdown voltage of the polyimide film and the pseudo device multilayer structure body was measured in a form that accords to JIS C2110. As a measurement apparatus, a HAT-300-100RHO type manufactured by Yamayo Tester Co., Ltd. was used.

Observation of Agglomeration Structure of Inorganic Filler

A sample piece having a thickness of 50 μm of the fabricated polyimide film was prepared A cross-section obtained by cutting out this sample piece with use of an FIB processing apparatus (SMI2050: manufactured by Seiko Instruments Inc.) was observed at a magnification of 21000 times by using a transmission electron microscope (TEM, H-7650: manufactured by Hitachi, Ltd.). By this, the agglomeration state of the inorganic filler in the sample piece was observed.

TABLE 2

| | | | | | insulation | |
|---|---|---|---|---|---|---|
| | | glass | | | breakdown | |
| | heat | transition | melt | bonding | voltage | |
| | conductivity | temperature | viscoelasticity | strength | (kV) | |
| | (W/m · K) | (° C.) | (MPa) | (kN/m) | film | device |
| Example 1 | 3.0 | 150 | 190 | 0.70 | 5.6 | 2.8 |
| Example 2 | 3.0 | 140 | 160 | 0.75 | 5.6 | 3.0 |
| Example 3 | 3.2 | 147 | 170 | 0.72 | 6.1 | 2.6 |
| Example 4 | 3.0 | 150 | 190 | 0.70 | 4.8 | 1.1 |
| Example 5 | 4.0 | 150 | 190 | 0.70 | 5.6 | 2.8 |
| Example 6 | 3.0 | 150 | 190 | 0.70 | 8.4 | 4.2 |
| Comparative | 3.0 | 245 | 2000 | ≦0.1 | 5.5 | — |
| Example 1 | | | | | | |
| Comparative | 1.5 | 150 | 180 | 0.72 | 5.5 | 2.8 |
| Example 2 | | | | | | |
| Comparative | 2.2 | 150 | 310 | 0.3 | 5.5 | 2.7 |
| Example 3 | | | | | | |
| Comparative | 0.7 | 150 | 190 | 0.70 | 5.8 | 2.9 |
| Example 4 | | | | | | |
| Comparative | 1.5 | 150 | 200 | ≦0.1 | 5.5 | — |
| Example 5 | | | | | | |
| Comparative | 1.1 | 150 | 190 | 0.70 | 5.6 | 2.8 |
| Example 6 | | | | | | |
| Comparative | 0.4 | 150 | 190 | 0.70 | 5.6 | 2.8 |
| Example 7 | | | | | | |
| Comparative | 3.1 | 150 | 200 | ≦0.1 | 5.6 | — |
| Example 8 | | | | | | |

*not measured yet because polyimide film was not bonded to metal foil, and the device could not be formed.

It will be understood that the polyimide films of Examples 1 to 6 satisfy all of a heat conductivity of 3.0 W/m·K or more, an insulation breakdown voltage above or equal to a constant value, and a sufficient bonding strength. Among these, it will be understood that a polyimide film containing an inorganic filler (B) having a high aspect ratio gains a high heat conductivity. In addition, it will be understood that the polyimide film of Example 2 containing a diamine represented by the formula (3) has a low glass transition temperature and can gain a good bonding strength to a copper foil. Further, as shown in Example 6, the polyimide film obtained by passing through the applying and drying step for two times has a higher insulation breakdown voltage and therefore has a higher reliability than the polyimide film (Example 1) having the same thickness obtained by passing through the applying and drying step for once.

In addition, as shown in FIGS. 4(A) and 4(B), in the TEM photograph of the polyimide film obtained in the Examples, an agglomeration structure of the inorganic filler was observed. In addition, it will be understood that a high affinity between the resin and the inorganic filler generates, and there are less voids (voids) between the resin and the inorganic filler.

In contrast, the polyimide films of Comparative Examples 1 to 8 do not simultaneously satisfy a high heat conductivity, insulation breakdown voltage, and a sufficient bonding strength.

Specifically, it will be understood that the polyimide film of Comparative Example 1 has a high glass transition temperature and a high melt viscoelasticity, and therefore cannot be bonded to a copper foil. It will be understood that the polyimide film of Comparative Example 2 has a content of the inorganic filler (B) of less than 40 weight %, so that a sufficient heat conductivity is not obtained; and the polyimide film of Comparative Example 3 has a content of the inorganic filler (B) exceeding 70 weight %, so that the bonding strength to the copper foil considerably decreases while having a certain heat conductivity. It will be understood that the polyimide film of Comparative Example 4 has an aspect ratio of the inorganic filler (B) of less than 9, so that a sufficient heat conductivity is not obtained. In addition, from comparison between Example 1 and Comparative Example 5, it will be understood that a heat conductivity as high as that of Example 1 is not obtained even when a large amount of the inorganic filler (B) having an aspect ratio of 6 or less is put thereinto. From Comparative Examples 7 and 8, it will be understood that, in order to obtain a heat conductivity with spherical alumina (having an aspect ratio of about 1) that is above or equal to a constant value, a large amount of spherical alumina will be needed, leading to decrease in the bonding property to a copper foil.

The present application claims priority rights based on Japanese Patent Application No. 2009-158493 filed on Jul. 3, 2009 and Japanese Patent Application No. 2009-235645 filed on Oct. 9, 2009. The contents described in the specifications of these applications are all incorporated into the specification of the present application.

### INDUSTRIAL APPLICABILITY

By using the resin composition of the present invention as an insulating resin layer between a conductor layer and other layers, a multilayer body can be obtained. The multilayer body can be applied, for example, to a substrate for a circuit, a heat-dissipating substrate, a component-incorporating substrate, or the like. In particular, the multilayer body can be a substrate for a circuit having a high heat conductivity. In addition, when an element (power device) having a high output capacity is mounted on a substrate for a circuit, the heat from the element can be efficiently dissipated. In addition, by enabling bonding at a low temperature, the mounting process can be improved.

### REFERENCE SIGNS LIST

10 semiconductor device
12 power device
14 solder layer
16 conductor layer
18 insulating resin layer
20 heat-dissipating plate

1. A resin composition containing a thermoplastic polyimide resin (A) having a glass transition temperature of 160° C. or less and an inorganic filler (B), wherein
the aspect ratio of the inorganic filler (B), which is represented by the length/thickness of the inorganic filler (B), is 9 or more; the content of the inorganic filler (B) is 40 to 70 weight % relative to the total weight of the resin composition; and
the resin composition has a melt viscoelasticity of 10 MPa or more and 300 MPa or less at 170° C.

2. The resin composition according to claim 1, wherein the inorganic filler (B) is boron nitride.

3. The resin composition according to claim 1, wherein
the thermoplastic polyimide resin (A) is a polyimide obtained by allowing a tetracarboxylic acid dianhydride component and a diamine component to react, and
the diamine component contains at least one of the diamines represented by the following general formulas (1), (2), and (3) 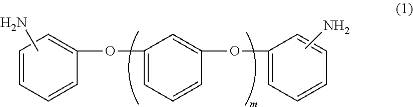
wherein m represents an integer of 1 to 13, 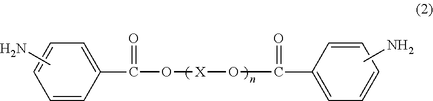
wherein n represents an integer of 1 to 50, and X each independently represents an alkylene group having a carbon number of 1 to 10, 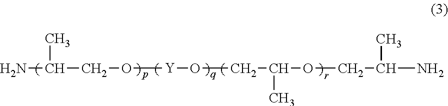
wherein p, q, and r each independently represent an integer of 0 to 10, and Y each independently represents an alkylene group having a carbon number of 1 to 10.

4. A multilayer body comprising:
an insulating resin layer made of the resin composition according to claim 1; and
a conductor layer disposed on one surface or on both surfaces of the insulating resin layer.

5. The multilayer body according to claim 4, wherein
the insulating resin layer is formed by laminating and thermally press-bonding two or more dry films made of the resin composition according to claim 1, or by repetitively applying and drying the resin composition according to claim 1 for two or more times.

6. A semiconductor device comprising:
an insulating resin layer made of the resin composition according to claim 1;
a conductor layer disposed on one surface or on both surfaces of the insulating resin layer, the conductor layer having a predetermined circuit pattern; and
a semiconductor element joined to the conductor layer.

7. The semiconductor device according to claim 6, wherein the semiconductor element is a semiconductor element for electric power having an output capacity of 100 VA or more.

8. The semiconductor device according to claim 6, further comprising a heat-dissipating plate on which the insulating resin layer is disposed.

9. The semiconductor device according to claim 8, wherein the insulating resin layer is bonded to the conductor layer and the heat-dissipating plate at 10° C. or more and 200° C. or less.

10. The semiconductor device according to claim 6, wherein
the insulating resin layer has a thickness of 50 μm or more and 200 μm or less, and has an insulation breakdown voltage of 20 kV/mm or more and 300 kV/mm or less.

11. The semiconductor device according to claim 6, wherein
the insulating resin layer is formed by laminating and thermally press-bonding two or more dry films made of the resin composition according to claim 1, or by repetitively applying and drying the resin composition according to claim 1 for two or more times.

12. A film made of a resin composition containing a thermoplastic polyimide resin (A) having a glass transition temperature of 160° C. or less and an inorganic filler (B), wherein
the aspect ratio of the inorganic filler (B), which is represented by the length/thickness of the inorganic filler (B), is 9 or more; the content of the inorganic filler (B) is 40 to 70 weight % relative to the total weight of the resin composition;
the resin composition has a melt viscoelasticity of 10 MPa or more and 300 MPa or less at 170° C.; and
the film has a heat conductivity of 3.0 W/m·K or more in the thickness direction.

13. The film according to claim 12, wherein
the film does not contain secondary particles connects one surface with the other surface of the film.
